(19) United States
(12) Patent Application Publication
(10) Pub. No.: US 2016/0131694 A1
(43) Pub. Date: May 12, 2016

(54) PROBLEM MONITORING IN CABLE SYSTEM WITH FUSES

(71) Applicant: KONINKLIJKE PHILIPS N.V., Eindhoven (NL)

(72) Inventors: Hong Chen, Shanghai (CN); Xiaobo Jiang, Eindhoven (NL); Lei Fend, Shanghai (CN)

(21) Appl. No.: 14/899,042

(22) PCT Filed: Jun. 18, 2014
(86) PCT No.: PCT/EP2014/062869

§ 371 Date: Dec. 16, 2015

(30) Foreign Application Priority Data
Jul. 2, 2013 (CN) PCT/CN2013/078663
Oct. 22, 2013 (EP) 13189629.2

(51) Int. Cl. G01R 31/07; G01R 31/02

(52) U.S. Cl. CPC G01R 31/07; G01R 31/021

(57) ABSTRACT

Apparatuses (10) for reporting problems in cable systems comprising cables (101) and loads (111-115) connected to the cables via fuses (121-125) are provided with first circuits (1) for detecting the fuses (121-125) going from conducting to non-conducting modes or having reached non-conducting modes, second circuits (2) for changing impedances of the cable systems at locations near the apparatuses (10) by introducing one or more impedance elements at the locations, and third circuits (3) for bringing the second circuits (2) into activated modes in response to detection results from the first circuits (1). The second circuits (2) may comprise capacitors (4) and the third circuits (3) may comprise switches (5). Devices (20) at central locations for detecting the problems comprise monitors (21) for monitoring, per time-interval, first values of parameters of voltage/current signals or second values of factors depending on the voltage/current signals and comparators (22) for comparing values from different time-intervals with each other. The values change in response to changes in impedances of cable systems at locations near the apparatuses (10).

### FIELD OF THE INVENTION

The invention relates to an apparatus for reporting a problem in a cable system, the cable system comprising a cable and a load connected to the cable via a fuse.

The invention further relates to an arrangement comprising the apparatus, to a device for detecting the problem in the cable system, to the cable system, to a package system, and to a method.

Examples of such a problem are broken fuses. Examples of such a load are lamps and other units that need to be supplied/powered/fed electrically.

### BACKGROUND OF THE INVENTION

CN 101635077 A discloses an anti-theft detection method for a road lamp cable wherein a variable frequency input current signal is injected into the road lamp cable and wherein output current signals and output voltage signals are to be measured for different frequencies of the input current signal and wherein resonance frequencies of road lamps are to be taken into account and wherein a number of actual road lamps needs to be known. This way, in a relatively complex manner, the road lamp cable can be monitored.

CN 201690648 U discloses an intelligent street lamp system based on a wireless sensing network such as GPRS or 3G. This way, in a relatively complex manner, the street lamp system can be monitored.

### SUMMARY OF THE INVENTION

It is an object of the invention to provide an improved apparatus. Further objects of the invention are to provide an arrangement, an improved device, a cable system, a package system and an improved method.

According to a first aspect, an apparatus is provided for reporting a problem in a cable system, the cable system comprising a cable and a load connected to the cable via a fuse, the apparatus comprising

a first circuit for detecting the fuse going from a conducting mode to a non-conducting mode or having reached a non-conducting mode,
a second circuit for, in an activated mode, changing an impedance of the cable system at a location near the apparatus by introducing one or more impedance elements at the location, and
a third circuit for bringing the second circuit into the activated mode in response to a detection result from the first circuit.

The apparatus reports a problem, such as a broken fuse, in a cable system that comprises a cable and a load connected to the cable via a fuse by changing an impedance of the cable system at a location near the apparatus, but only in case it has been detected that the fuse is broken. Thereto, via a first circuit, it is detected that the fuse is going from a conducting mode to a non-conducting mode or has reached a non-conducting mode. The conducting mode is a mode wherein the fuse is conducting and/or is connecting the cable and the load via a relatively small resistance value, such as for example <100 Ohm, preferably <10 Ohm, more preferably <1 Ohm. The non-conducting mode is a mode wherein the fuse is not conducting and/or is not connecting the cable and the load via a relatively small resistance value but is showing at least a relatively large resistance value, such as for example >1 k Ohm, preferably >10 k Ohm, more preferably >100 k Ohm. Via a second circuit, an impedance of the cable system is changed at a location near the apparatus, but only after the second circuit has been brought into an activated mode. Via a third circuit, the second circuit is brought into the activated mode in response to a detection result from the first circuit. As a result, the apparatus located close to the fuse and/or the load can report the problem to a device located at a central location, owing to the fact that a change at the central location in at least one of a voltage signal present across the cable and a current signal flowing through the cable will be indicative for the problem. This is a great advantage.

Other kinds of problems may be reported as well, such as a broken connection between the fuse and the load and/or a missing load and/or a malfunction of the load etc. At a start of the apparatus, such as for example shortly after installation or shortly after a reset, the second circuit will be de-activated and waiting to be activated. In the de-activated mode, the second circuit may be invisible to the cable system and may not have any influence on the cable system. Changing the impedance of the cable system at the location near the apparatus may be realized through introducing one or more impedance elements at that location.

An embodiment of the apparatus is defined by said changing of the impedance of the cable system at the location near the apparatus comprising a reactive change. A reactive change can be monitored well.

An embodiment of the apparatus is defined by said reactive change comprising a capacitive change. A capacitive change can be monitored easily.

An embodiment of the apparatus is defined by the first circuit comprising a detector for detecting a current signal flowing through the load or through the fuse or detecting a voltage signal present across the load or across the fuse or detecting another signal representative for the fuse going from the conducting mode to the non-conducting mode or having reached the non-conducting mode. Many different ways will be possible to detect a mode of the fuse. The detector may comprise a relay coil, a transistor, a thyristor, a triac etc. possibly with further circuitry.

An embodiment of the apparatus is defined by the second circuit comprising a capacitor, and the third circuit comprising a switch. The capacitor is suited for changing the impedance of the cable system at the location near the apparatus, and the switch is suited for activating and de-activating the capacitor. Other components are not to be excluded and will be possible too. The switch may comprise a relay contact, a transistor, a thyristor, a triac etc. possibly with further circuitry.

An embodiment of the apparatus is defined by the capacitor and the switch forming part of a first serial connection, the fuse and the load forming part of a second serial connection, the first and second serial connections being coupled in parallel to each other. Other constructions are not to be excluded and will be possible too.

An embodiment of the apparatus is defined by the switch going from a non-conducting mode into a conducting mode in response to the detection result from the first circuit and staying in this conducting mode until a reset of the switch. Preferably, the switch will stay into the conducting mode until the reset of the switch, such that the switch is not only in the conducting mode at times at which the loads are supplied/powered/fed but also at times at which these loads are not supplied/powered/fed. The conducting mode is a mode wherein the switch is conducting and/or is connecting the capacitor to (both conductors of) the cable via a relatively small resistance value, such as for example <100 Ohm, preferably <10 Ohm, more preferably <1 Ohm. The non-conducting mode is a mode wherein the switch is not conducting and/or is not connecting the capacitor to (both conductors of) the cable via a relatively small resistance value but is showing at least a relatively large resistance value, such as for example >1 k Ohm, preferably >10 k Ohm, more preferably >100 k Ohm. A reset may comprise a local reset, a remote reset and a replacement.

According to a second aspect, an arrangement is provided comprising the apparatus as defined above and further comprising the load and/or the fuse.

According to a third aspect, a device is provided for detecting a problem in a cable system, the cable system comprising a cable, a load connected to the cable via a fuse and an apparatus as described above, the device comprising

a monitor for monitoring, per time-interval, a first value of a parameter of at least one of a voltage signal present across the cable and a current signal flowing through the cable or for monitoring, per time-interval, a second value of a factor depending on at least one of the voltage signal and the current signal, and
a comparator for comparing first values from different time-intervals with each other or for comparing second values from different time-intervals with each other, a difference between compared values larger than a threshold being indicative for the problem, wherein the difference between compared values larger than the threshold is caused by the introduced one or more impedance elements of the apparatus.

An embodiment of the device is defined by the parameter comprising a phase of the current signal or a phase of the voltage signal. In case a voltage source is used for providing the voltage signal, the phase of the current signal will change at the central location in case at the location of the apparatus the capacitor is activated and connected to the cable for changing its impedance value. In case a current source is used for providing the current signal, the phase of the voltage signal will change at the central location in case at the location of the apparatus the capacitor is activated and connected to the cable for changing its impedance value.

An embodiment of the device is defined by the factor comprising a power factor. The power factor is defined to be equal to the true or real power divided by the apparent power and therefore also depends on the voltage and current signals.

An embodiment of the device is defined by the first value of the parameter and the second value of the factor being changed in response to a change in an impedance of the cable system at a location near the apparatus as defined above.

According to a fourth aspect, a cable system is provided comprising a cable and a load connected to the cable via a fuse and further comprising the apparatus as defined above and/or the device as defined above.

According to a fifth aspect, a package system is provided comprising the apparatus as defined above and the device as defined above.

According to a sixth aspect, a method is provided for detecting a problem in a cable system, the cable system comprising a cable, a load connected to the cable via a fuse and an apparatus as described above, the method comprising steps of

monitoring, per time-interval, a first value of a parameter of at least one of a voltage signal present across the cable and a current signal flowing through the cable or a second value of a factor depending on at least one of the voltage signal and the current signal, and
comparing first values from different time-intervals with each other or for comparing second values from different time-intervals with each other, a difference between compared values larger than a threshold being indicative for the problem, wherein the difference between compared values larger than the threshold is caused by the introduced one or more impedance elements of the apparatus.

A basic idea is that a mode of a fuse is to be detected and that in response to a detection result an impedance of the cable system at a location near the apparatus is to be changed.

A problem to provide an improved apparatus and an improved device and an improved method has been solved. A further advantage is that the improved apparatus and the improved device are simple, low cost and robust.

These and other aspects of the invention will be apparent from and elucidated with reference to the embodiments described hereinafter.

### BRIEF DESCRIPTION OF THE DRAWINGS

In the drawings:

FIG. 1 shows a prior art cable system,

FIG. 2 shows an apparatus, a fuse and a load,

FIG. 3 shows a first embodiment of the apparatus,

FIG. 4 shows a second embodiment of the apparatus,

FIG. 5 shows a device,

FIG. 6 shows a problem occurrence,

FIG. 7 shows a problem report, and

FIG. 8 shows a prior art load.

### DETAILED DESCRIPTION OF EMBODIMENTS

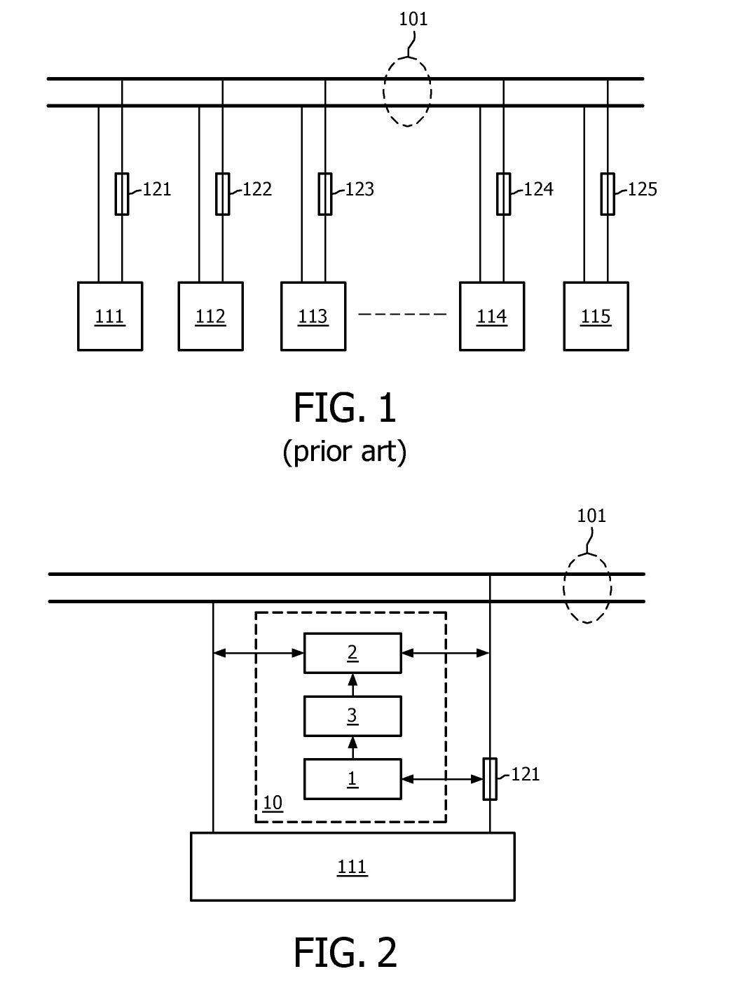

In the FIG. 1, a prior art cable system is shown, comprising a cable 101, loads 111-115 and fuses 121-125. Each load 111-115 is coupled to a first conductor of the cable 101 indirectly via a fuse 121-125 and to a second conductor of the cable 101 directly. The load 111-115 may be any kind of load, such as a lamp, for example comprising one or more light emitting diodes. The fuse 121-125 may be any kind of fuse. Alternatively, the second conductor of the cable 101 may be arranged otherwise, for example via the ground.

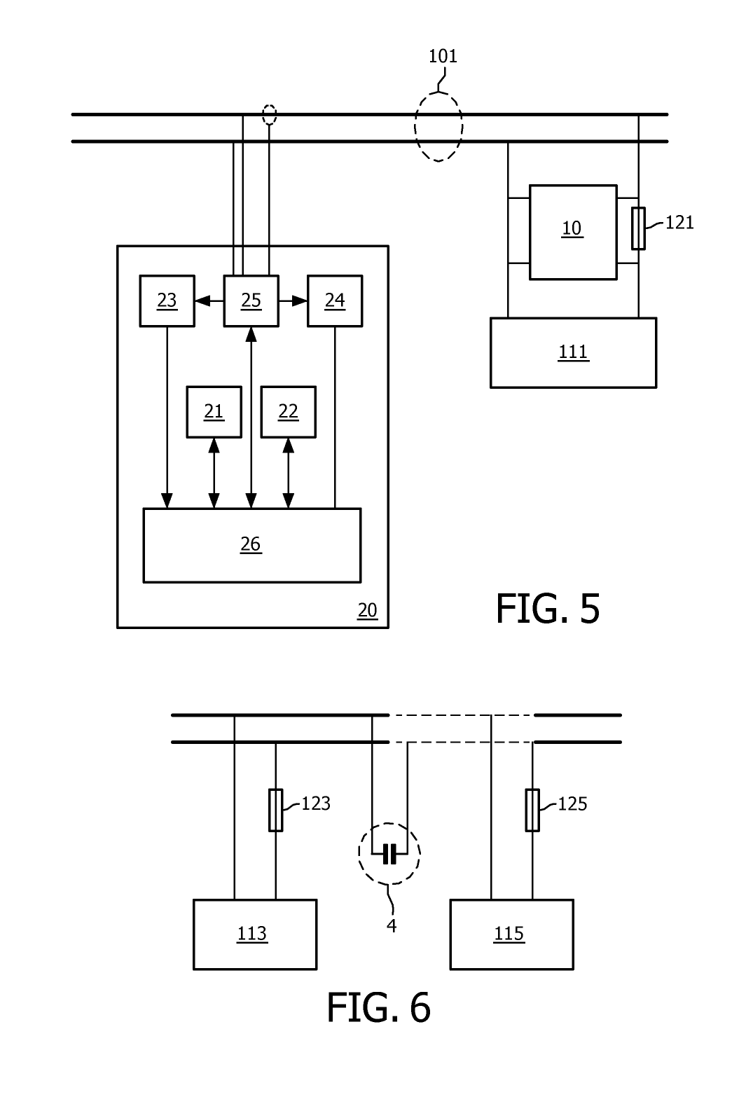

In the FIG. 2, an apparatus 10 is shown. The apparatus 10 reports a problem in a cable system comprising a cable 101 and a load 111 connected to the cable 101 via a fuse 121. The apparatus 10 comprises a first circuit 1 for detecting the fuse 121 going from a conducting mode to a non-conducting mode or having reached a non-conducting mode. The apparatus 10 further comprises a second circuit 2 connectable to the cable 101 for, in an activated mode, changing an impedance of the cable system at a location near the apparatus 10, such that a change in the impedance can be monitored by a device 20 shown in the FIG. 5 and further discussed at the hand of the FIG. 5. The apparatus 10 further comprises a third circuit 3 for bringing the second circuit 2 into an activated mode in response to a detection result from the first circuit 1. So, at a start of the apparatus 10, the second circuit 2 is in a de-activated mode.

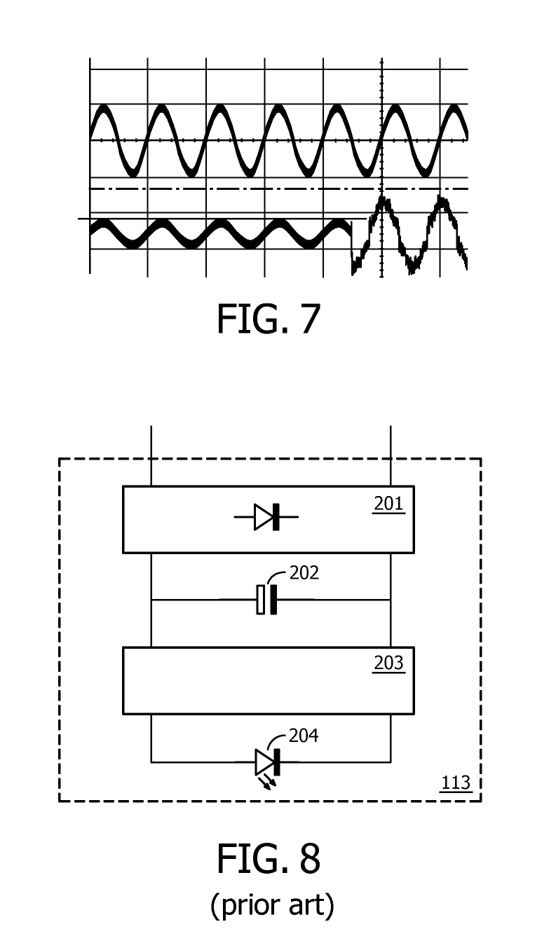

Preferably, said change in the impedance of the cable system at the location near the apparatus 10 comprises a reactive change, and said reactive change comprises a capacitive change. In case a voltage source is used for providing a voltage signal, the capacitive change will result in a phase of a current signal flowing through the cable 101 being changed, as shown in the FIGS. 6 and 7 and further discussed at the hand of the FIGS. 6 and 7. It will also result in a power factor being changed.

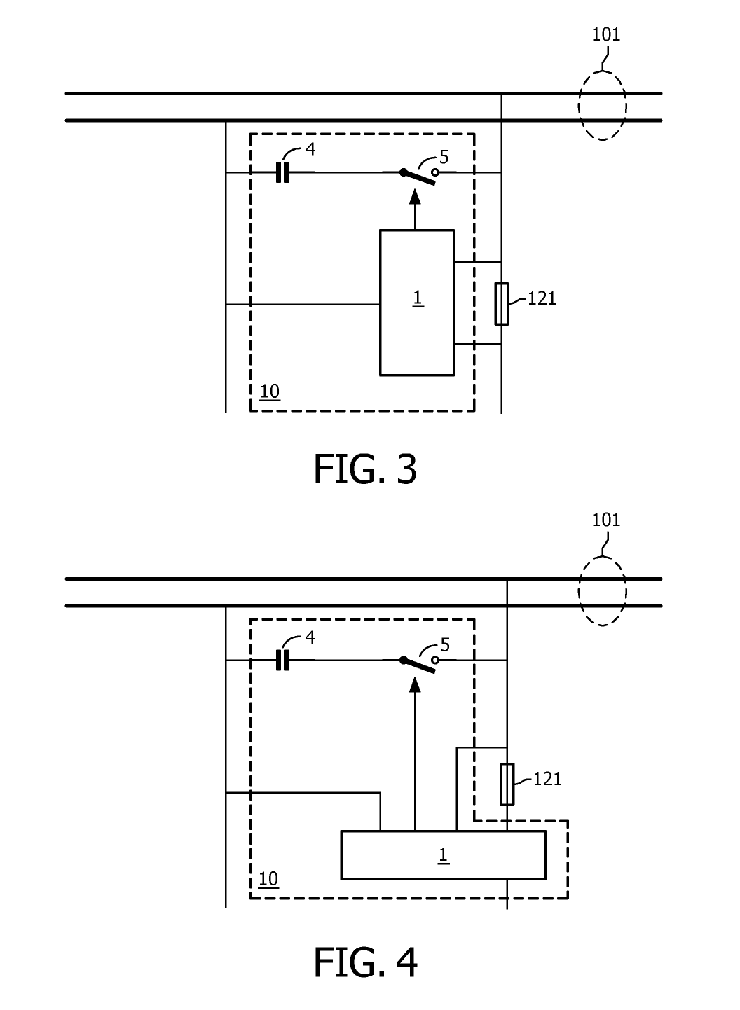

In the FIG. 3, a first embodiment of the apparatus 10 is shown. Here, as an example only, the second circuit 2 comprises a capacitor 4, and the third circuit 3 comprises a switch 5. The capacitor 4 and the switch 5 are connected serially and form part of a first serial connection coupled to both conductors of the cable 101. The fuse 121 and the load 111 (the load 111 is not shown here) form part of a second serial connection coupled in parallel to the first serial connection. Here, the first circuit 1 has a first terminal coupled to the first conductor and to one side of the fuse 121, a second terminal coupled to the other side of the fuse 121, and a third terminal coupled to the second conductor of the cable 101. This first circuit 1 for example comprises a detector for detecting a voltage signal present across the load 111 or across the fuse 121 or detecting another signal representative for the fuse 121 going from the conducting mode to the non-conducting mode or having reached the non-conducting mode. The first circuit 1 may further for example comprise a comparator for comparing the voltage signal with a first reference signal. In response to a change in the voltage signal, such as an increase of the voltage signal present across the fuse 121 or a decrease of the voltage signal present across the load 111, the first circuit 1 brings the switch 5 into a conducting mode. Preferably, the switch 5 stays in this conducting mode until a reset of the switch 5. As a result, in response to the fuse 121 getting broken, the capacitor 4 is activated and connected to the cable 101 for changing its impedance value, that will result in a phase of a current signal flowing through the cable 101 being changed as further described at the hand of the FIGS. 6 and 7.

In the FIG. 4, a second embodiment of the apparatus 10 is shown. Here, again as an example only, the second embodiment differs from the first embodiment in that the first circuit 1 has a first terminal coupled to the first conductor and to one side of the fuse 121, a second terminal coupled to the other side of the fuse 121, a third terminal coupled to the second conductor of the cable 101 and to one side of the load 111, and a fourth terminal coupled to the other side of the load 111. This first circuit 1 for example comprises a detector for detecting a current signal flowing through the load 111 or through the fuse 121 or detecting another signal representative for the fuse 121 going from the conducting mode to the non-conducting mode or having reached the non-conducting mode. The first circuit 1 may further for example comprise a comparator for comparing the current signal with a second reference signal. In response to a change in the current signal, such as a decrease of the current signal flowing through the load 111 or through the fuse 121, the first circuit 1 brings the switch 5 into a conducting mode. Preferably, the switch 5 stays in this conducting mode until a reset of the switch 5. As a result, in response to the fuse 121 getting broken, the capacitor 4 is activated and connected to the cable 101 for changing its impedance value, that will result in a phase of a current signal flowing through the cable 101 being changed as further described at the hand of the FIGS. 6 and 7.

In the FIG. 5, a device 20 is shown. The device 20 for detecting a problem in a cable system comprising the cable 101 and the load 111 connected to the cable 101 via the fuse 121 comprises for example an interface 25 coupled to the conductors of the cable 101. The device 20 further comprises for example a voltage detector 23 coupled to the interface 25 for detecting a voltage signal present across the cable 101. The device 20 further comprises for example a current detector 24 coupled to the interface 25 for detecting a current signal flowing through the cable 101. The device 20 further comprises for example a processor 26 coupled to the voltage detector 23, the current detector 24 and the interface 25 for controlling and/or calculation and/or presentation purposes, possibly via a man-machine-interface not shown and coupled to the processor 26.

The device 20 further comprises a monitor 21 for monitoring, per time-interval, a first value of a parameter of at least one of the voltage signal present across the cable 101 and the current signal flowing through the cable 101 or for monitoring, per time-interval, a second value of a factor depending on at least one of the voltage signal and the current signal. The device 20 further comprises a comparator 22 for comparing first values from different time-intervals with each other or for comparing second values from different time-intervals with each other. A difference between compared values larger than a threshold being will be indicative for the problem. Usually, the first value of the parameter and the second value of the factor will be changed in response to a change in an impedance of the cable system at a location near the apparatus 10. First values of the parameter and second values of the factor may be stored in a memory (not shown) that is coupled to or forms part of the processor 26.

Preferably, the parameter comprises a phase of the current signal, or a phase of the voltage signal, and the factor comprises a power factor that can for example be calculated by the processor 26 at the hand of the voltage and current signals.

In the FIG. 6, a problem occurrence is shown. The fuses 123 and 125 are in conducting modes. The fuse 124 is no longer in a conducting mode, and as a result, the capacitor 4 has been activated and connected to the cable 101 to change its impedance.

In the FIG. 7, a problem report is shown. The voltage signal present across the cable 101 as shown in the upper graph is a sine wave. The current signal flowing through the cable 101 as shown in the lower graph experiences a phase shift or a phase jump shortly after the capacitor 4 is activated and connected to the cable 101 for changing its impedance value.

In the FIG. 7, a voltage source is used for providing the voltage signal, in which case the phase of the current signal flowing through the cable 101 will be changed in response to said capacitive change in the impedance of the cable system at the location near the apparatus 10. However, alternatively, but not shown here, a current source may be used for providing the current signal, in which case the phase of the voltage signal present across the cable 101 will be changed in response to said capacitive change in the impedance of the cable system at the location near the apparatus 10 etc.

Usually, the third circuit 3 in the apparatus 10 will be able to activate the second circuit 2 during the night (in case the corresponding fuse gets broken), when the loads 111-115, such as lamps, are consuming power, and the voltage and current signals are being supplied via the cable 101 to the loads 111-115. When the switch 5 has a memory function, it will stay in the conducting mode until a reset of the switch 5. Also during the night, the monitor 21 and the comparator 22 will then be able to monitor and compare.

However, alternatively, it should not be excluded that during the day other voltage and current signals are being supplied via the cable 101, not for feeding the loads 111-115 but only for allowing the apparatus 10 to report a problem, such as for example a disconnection between the fuse 121 and the load 111. And, for example for other kinds of loads 111-115, the voltage and current signals may be supplied at arbitrary times for feeding the other kinds of loads. Finally, it should not be excluded that the apparatus 10 may be provided with its own power supply etc.

In the FIG. 8, a prior art load 113 is shown. This prior art load 113 comprises a rectifier bridge 201. Inputs of the rectifier bridge 201 are inputs of the load 113. Outputs of the rectifier bridge 201 are coupled to inputs of a dc-dc-converter 203 and to a capacitor 202. Outputs of the dc-dc-converter 203 are coupled to one or more light emitting diodes 204.

Many alternatives will be possible to the embodiments shown in the FIG. 2-8. For example, in the FIGS. 3 and 4, the capacitor 4 and the switch 5 may each be replaced by one or more other components and/or may each be connected otherwise. For example, in the FIGS. 3 and 4, the first circuit 1 may consist of different sub-circuits and/or may be connected differently. As a very simple example, the first circuit 1 may be a coil of a relay, with the switch 5 then comprising the contacts of this relay. When the fuse 121-125 stops being conductive, the relay goes into another mode and its contacts are mutually connected (here, the relay might be made capable of experiencing a difference between (A) the fuse 121-125 stopping to conduct and (B) the power on the cable 101 being cut off, then more circuitry may in this particular case be necessary). More complicated embodiments of the first circuit 1 are therefore not to be excluded and may comprise a transistor, a thyristor, a triac etc. possibly with further circuitry etc. Similarly, the second and third circuits 2, 3 may comprise a transistor, a thyristor, a triac etc. possibly with further circuitry etc.

For example in the FIG. 5, in the device 20, the interface 25 can be left out in case the voltage detector 23 and the current detector 24 can communicate more directly with the cable 101. Further, some or all functions of the voltage detector 23, current detector 24, the monitor 23 and the comparator 24 may be integrated into the processor 26, and vice versa. Any unit 21-26 may be divided into sub-units, and any pair of units 21-26 may be combined into a larger unit etc. Finally, in the FIG. 8, the rectifier bridge 201, the capacitor 202, the dc-dc-converter 203 and the one or more light emitting diodes 204 of whatever kind and in whatever construction are examples only, other kinds of loads 111-115 are not to be excluded.

Instead of a second circuit 2 in the form of a capacitor 4, a second circuit 2 in the form of a relatively small resistor with a relatively high power dissipation capability could be used, that is brought into an activated mode by the third circuit 3 only for a relatively short period of time, such as for example 1 μsec. or 1 nsec. and for example once per minute or once per hour etc. This way, a relatively short voltage decrease or a relatively short current increase can be detected by the device 20 etc. So, the second circuit 2 and the third circuit 3 should not be looked at too limitedly.

Summarizing, apparatuses 10 for reporting problems in cable systems comprising cables 101 and loads 111-115 connected to the cables via fuses 121-125 are provided with first circuits 1 for detecting the fuses 121-125 going from conducting to non-conducting modes or having reached non-conducting modes, second circuits 2 for changing impedances of the cable systems at locations near the apparatuses 10, and third circuits 3 for bringing the second circuits 2 into activated modes in response to detection results from the first circuits 1. The second circuits 2 may comprise capacitors 4 and the third circuits 3 may comprise switches 5. Devices 20 at central locations for detecting the problems comprise monitors 21 for monitoring, per time-interval, first values of parameters of voltage/current signals or second values of factors depending on the voltage/current signals and comparators 22 for comparing values from different time-intervals with each other. The values change in response to changes in impedances of cable systems at locations near the apparatuses 10.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. An apparatus for reporting a problem in a cable system, the cable system comprising a cable and a load connected to the cable via a fuse, the apparatus comprising
a first circuit for detecting the fuse going from a conducting mode to a non-conducting mode or having reached a non-conducting mode,
a second circuit for, in an activated mode, changing an impedance of the cable system at a location near the apparatus by introducing one or more impedance elements at the location, and
a third circuit for bringing the second circuit into the activated mode in response to a detection result from the first circuit.

2. The apparatus as defined in claim 1, said changing of the impedance of the cable system at the location near the apparatus comprising a reactive change.

3. The apparatus as defined in claim 2, said reactive change comprising a capacitive change.

4. The apparatus as defined in claim 1, the first circuit EH comprising a detector for detecting a current signal flowing through the load or through the fuse or detecting a voltage signal present across the load or across the fuse or detecting another signal representative for the fuse going from the conducting mode to the non-conducting mode or having reached the non-conducting mode.

5. The apparatus as defined in claim 1, the second circuit comprising a capacitor, and the third circuit comprising a switch.

6. The apparatus as defined in claim 5, the capacitor and the switch forming part of a first serial connection, the fuse and the load forming part of a second serial connection, the first and second serial connections being coupled in parallel to each other.

7. The apparatus as defined in claim 5, the switch going into a conducting mode in response to the detection result from the first circuit and staying in this conducting mode until a reset of the switch.

8. An arrangement comprising the apparatus as defined in claim 1 and further comprising the load and/or the fuse.

9. A device for detecting a problem in a cable system, the cable system comprising a cable, a load connected to the cable via a fuse and an apparatus for reporting the problem according to claim 1, the device comprising
a monitor for monitoring, per time-interval, a first value of a parameter of at least one of a voltage signal present across the cable and a current signal flowing through the cable or for monitoring, per time-interval, a second value of a factor depending on at least one of the voltage signal and the current signal, and
a comparator for comparing first values from different time-intervals with each other or for comparing second values from different time-intervals with each other, a difference between compared values larger than a threshold being indicative for the problem, wherein the difference between compared values larger than the threshold is caused by the introduced one or more impedance elements of the apparatus.

10. The device as defined in claim 9, the parameter comprising a phase of the current signal or a phase of the voltage signal.

11. The device as defined in claim 9, the factor comprising a power factor.

12. The device as defined in claim 9, the first value of the parameter and the second value of the factor being changed in response to a change in an impedance of the cable system at a location near the apparatus.

13. A cable system comprising a cable and a load connected to the cable via a fuse and further comprising the apparatus as defined in claim 1.

14. A package system comprising the apparatus as defined in claim 1.

15. A method for detecting a problem in a cable system, the cable system comprising a cable, a load connected to the cable via a fuse and an apparatus according to claim 1, the method comprising steps of
monitoring, per time-interval, a first value of a parameter of at least one of a voltage signal present across the cable and a current signal flowing through the cable or a second value of a factor depending on at least one of the voltage signal and the current signal, and
comparing first values from different time-intervals with each other or for comparing second values from different time-intervals with each other, a difference between compared values larger than a threshold being indicative for the problem, wherein the difference between compared values larger than the threshold is caused by the introduced one or more impedance elements of the apparatus.
